(19) United States
(12) Patent Application Publication
(10) Pub. No.: US 2009/0066232 A1
(43) Pub. Date: Mar. 12, 2009

(54) ORGANIC LIGHT EMITTING DEVICE

(76) Inventors: Hongmo Koo, Gumi-city (KR); Daeyang Oh, Gumi-city (KR)

Correspondence Address: KED & ASSOCIATES, LLP, P.O. Box 221200, Chantilly, VA, 20153-1200, US

(21) Appl. No.: 11/967,744

(22) Filed: Dec. 31, 2007

(30) Foreign Application Priority Data
Sep. 12, 2007 (KR) 10-2007-0092678

(51) Int. Cl. H01J 1/62

(52) U.S. Cl. 313/504

(57) ABSTRACT

An organic light emitting device is disclosed. The organic light emitting device includes a first substrate, an organic light emitting element on the first substrate, a second substrate facing the first substrate, and a seal member attaching the first substrate to the second substrate. The organic light emitting element includes an emitting layer. At least one of layers constituting the emitting layer includes a phosphorescence material. The seal member has an absorptance that lies substantially in a range between 25% and 35% at a wavelength of external light of approximately 305 nm to 330 nm.

This application claims the benefit of Korean Patent Application No. 10-2007-0092678 filed on Sep. 12, 2007, which is hereby incorporated by reference.

### BACKGROUND OF THE DISCLOSURE

1. Field of the Disclosure

An exemplary embodiment relates to a display device, and more particularly, to an organic light emitting device.

2. Description of the Related Art

Due to development of a multimedia, importance of display devices such as flat panel displays (FPD) has been gradually increasing. Other displays such as a liquid crystal display (LCD), a plasma display panel (PDP), a field emission display (FED), and an organic light emitting device also being used.

An organic light emitting device may have a high response speed (of 1 ms or less), a low power consumption, and a self-luminance property. An organic light emitting device may also not have viewing problems. As such, organic light emitting device be considered as the next generation display devices.

The organic light emitting device is a display device for self-emitting in an emitting layer that includes an organic material that may be easily deteriorated by external moisture and oxygen. Therefore, the organic light emitting device may attempt to prevent the organic material of the emitting layer from being deteriorated.

Accordingly, the organic light emitting device includes a second substrate capable of sealing a first substrate including an organic light emitting element, coats a seal member at an external edge between the first substrate and the second substrate, and performs a sealing process. The seal member coated between the first substrate and the second substrate is cured by ultraviolet (UV) light to attach the first substrate to the second substrate.

In such a sealing process, an absorptance of the UV-cured seal member is considered. Further, a transmittance of the first substrate or the second substrate to which ultraviolet light is radiated is considered so as to properly radiate ultraviolet light to the seal member.

Therefore, an organic light emitting device capable of improving life span and reliability of elements has been proposed in consideration of the absorptance of the seal member or the transmittance of the substrate.

### SUMMARY OF THE DISCLOSURE

An exemplary embodiment provides an organic light emitting device capable of improving life span and reliability of elements.

In one aspect, an organic light emitting device comprises a first substrate, an organic light emitting element on the first substrate, the organic light emitting element including an emitting layer, at least one of layers constituting the emitting layer including a phosphorescence material, a second substrate facing the first substrate, and a seal member that attaches the first substrate to the second substrate, the seal member having an absorptance that lies substantially in a range between 25% and 35% at a wavelength of external light of approximately 305 nm to 330 nm.

In another aspect, an organic light emitting device comprises a first substrate, an organic light emitting element on the first substrate, the organic light emitting element including an emitting layer, at least one of layers constituting the emitting layer including a phosphorescence material, a second substrate facing the first substrate, and a seal member that attaches the first substrate to the second substrate, the seal member having an absorptance that lies substantially in a range between 25% and 35% at a wavelength of external light of approximately 305 nm to 330 nm, wherein at least one of the first substrate and the second substrate has a transmittance that lies substantially in a range between 50% and 70% at a wavelength of external light of approximately 305 nm to 330 nm.

In still another aspect, an organic light emitting device comprises a first substrate, an organic light emitting element on the first substrate, the organic light emitting element including an emitting layer, at least one of layers constituting the emitting layer including a phosphorescence material, a second substrate facing the first substrate, and a seal member that attaches the first substrate to the second substrate, wherein the seal member has an absorptance that lies substantially in a range between 25% and 35% at a wavelength of external light of approximately 305 nm to 330 nm, and a water vapor permeation rate greater than 0 and equal to or less than 10⁻²g/m²/day, and at least one of the first substrate and the second substrate has a transmittance that lies substantially in a range between 50% and 70% at a wavelength of external light of approximately 305 nm to 330 nm.

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention. In the drawings:

FIG. 1 is a bock diagram of an organic light emitting device according to an exemplary embodiment;

FIG. 2 is a plane view of the organic light emitting device;

FIGS. 3A and 3B are circuit diagrams of a subpixel of the organic light emitting device;

FIG. 4 is a cross-sectional view taken along line Z1-Z2 of FIG. 2;

FIGS. 5A to 6C illustrate various implementations of a color image display method in the organic light emitting device;

FIG. 6 is a cross-sectional view of the organic light emitting device;

FIG. 7 is a graph showing an absorptance of the seal member of the organic light emitting device; and

FIG. 8 is a graph showing a transmittance of a substrate of the organic light emitting device.

### DETAILED DESCRIPTION OF EMBODIMENTS

Reference will now be made in detail embodiments of the invention examples of which are illustrated in the accompanying drawings.

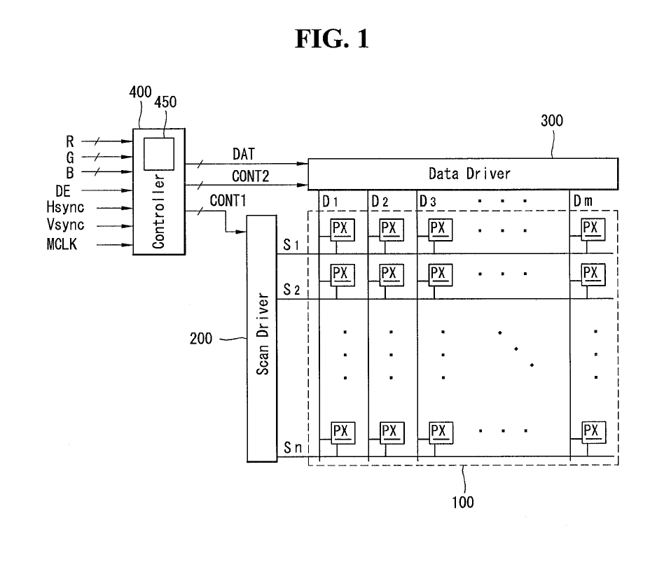

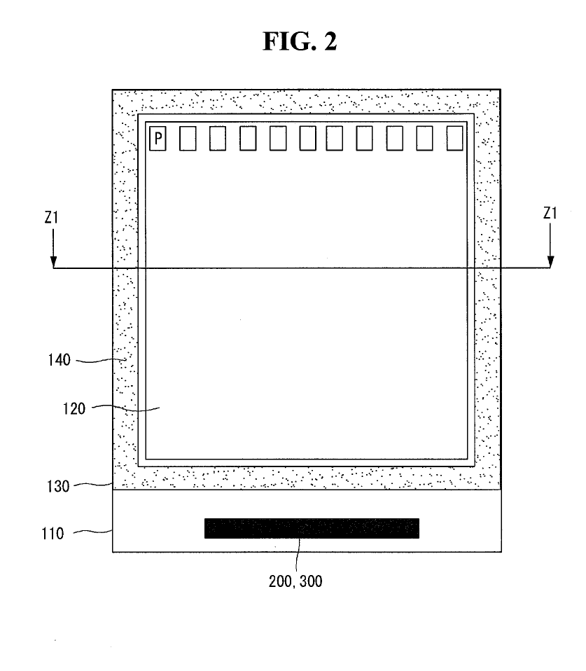

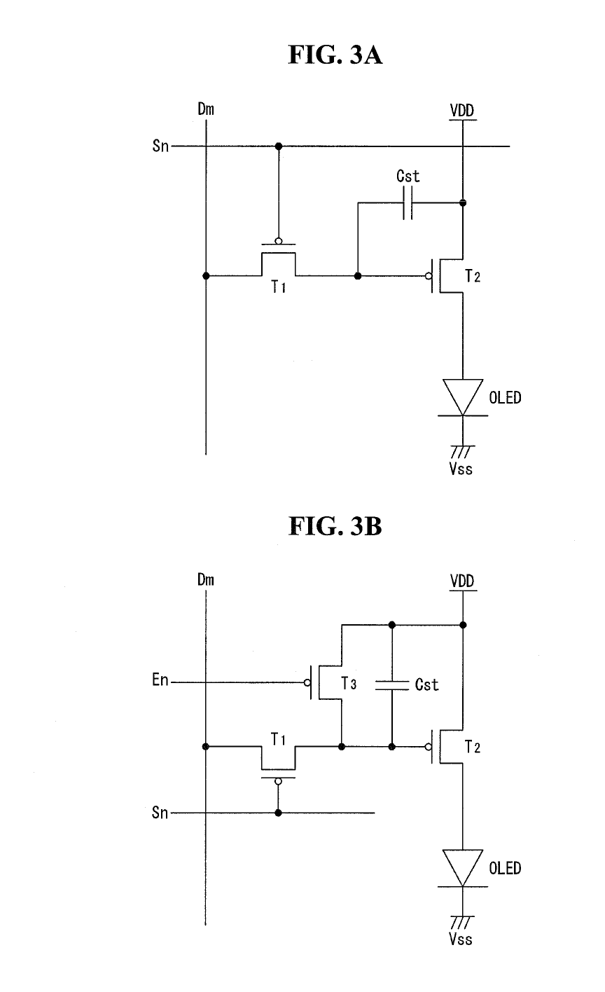

FIG. 1 is a bock diagram of an organic light emitting device according to an exemplary embodiment, FIG. 2 is a plane view of the organic light emitting device, and FIGS. 3A and 3B are circuit diagrams of a subpixel of the organic light emitting device.

As shown in FIG. 1, the organic light emitting device according to the exemplary embodiment includes a display panel 100, a scan driver 200, a data driver 300 and a controller 400.

The display panel 100 includes a plurality of signal lines S1 to Sn and D1 to Dm, a plurality of power supply lines (not shown), and a plurality of subpixels PX connected to the signal lines S1 to Sn and D1 to Dm and the power supply lines in a matrix form.

The plurality of signal lines S1 to Sn and D1 to Dm may include the plurality of scan lines S1 to Sn for sending scan signals and the plurality of data lines D1 to Dm for sending data signals. Each power supply line may send voltages such as a power voltage VDD to each subpixel PX.

Although the signal lines include the scan lines S1 to Sn and the data lines D1 to Dm in FIG. 1, the exemplary embodiment is not limited thereto. The signal lines may further include erase lines (not shown) for sending erase signals depending on a driving manner.

However, an erase line may not be used to send an erase signal. The erase signal may be sent through another signal line. For instance, although it is not shown, the erase signal may be supplied to the display panel 100 through the power supply line in case that the power supply line for supplying the power voltage VDD is formed.

As shown in FIG. 3A, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, and an organic light emitting diode (OLED) emitting light corresponding to the driving current.

As shown in FIG. 3B, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, an organic light emitting diode (OLED) emitting light corresponding to the driving current, and an erase switching thin film transistor T3 for erasing the data signal stored in the capacitor Cst in response to an erase signal sent through an erase line En.

When the organic light emitting device is driven in a digital driving manner that represents a gray scale by dividing one frame into a plurality of subfields, the pixel circuit of FIG. 3B can control an emission time by supplying an erase signal to a subfield whose a light-emission is shorter than an addressing time. The pixel circuit of FIG. 3B has an advantage capable of reducing a lowest luminance of the organic light emitting device.

A difference between driving voltages, e.g., the power voltages VDD and Vss of the organic light emitting device may change depending on the size of the display panel 100 and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) of | | | |
|---|---|---|---|
| display panel | VDD-Vss (R) | VDD-Vss (G) | VDD-Vss (B) |
| S < 3 inches | 3.5-10 (V) | 3.5-10 (V) | 3.5-12 (V) |
| 3 inches < S < 20 | 5-15 (V) | 5-15 (V) | 5-20 (V) |
| inches | | | |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Referring again to FIG. 1, the scan driver 200 is connected to the scan lines S1 to Sn of the display panel 100 to apply scan signals capable of turning on the switching thin film transistor T1 to the scan lines S1 to Sn, respectively.

The data driver 300 is connected to the data lines D1 to Dm of the display panel 100 to apply data signals indicating an output video signal DAT′ to the data lines D1 to Dm, respectively. The data driver 300 may include at least one data driving integrated circuit (IC) connected to the data lines D1 to Dm.

The data driving IC may include a shift register, a latch, a digital-to-analog (DA) converter, and an output buffer connected to one another in the order named.

When a horizontal sync start signal (STH) (or a shift clock signal) is received, the shift register can send the output video signal DAT to the latch in response to a data clock signal (HLCK). In case that the data driver 300 includes a plurality of data driving ICs, a shift register of a data driving IC can send a shift clock signal to a shift register of a next data driving IC.

The latch memorizes the output video signal DAT′, selects a gray voltage corresponding to the memorized output video signal DAT′ in response to a load signal, and sends the gray voltage to the output buffer.

The DA converter selects the corresponding gray voltage in response to the output video signal DAT′ and sends the gray voltage to the output buffer.

The output buffer outputs an output voltage (serving as a data signal) received from the DA converter to the data lines D1 to Dm, and maintains the output of the output voltage for 1 horizontal period (1 H).

The controller 400 controls an operation of the scan driver 200 and an operation of the data driver 300. The controller 400 may include a signal conversion unit 450 that gamma-converts input video signals R, G and B into the output video signal DAT′ and produces the output video signal DAT′.

The controller 400 produces a scan control signal CONT1 and a data control signal CONT2, and the like. Then, the controller 400 outputs the scan control signal CONT1 to the scan driver 200 and outputs the data control signal CONT2 and the processed output video signal DAT′ to the data driver 300.

The controller 400 receives the input video signals R, G and B and an input control signal for controlling the display of the input video signals R, G and B from a graphic controller (not shown) outside the organic light emitting device. Examples of the input control signal include a vertical sync signal Vsync, a horizontal sync signal Hsync, a main clock signal MCLK and a data enable signal DE.

Each of the driving devices 200, 300 and 400 may be directly mounted on the display panel 100 in the form of at least one IC chip, or may be attached to the display panel 100 in the form of a tape carrier package (TCP) in a state where the driving devices 200, 300 and 400 each are mounted on a flexible printed circuit film (not shown), or may be mounted on a separate printed circuit board (not shown).

Alternatively, each of the driving devices 200, 300 and 400 may be integrated on the display panel 100 together with the plurality of signal lines S1 to Sn and D1 to Dm or the thin film transistors T1, T2 and T3, and the like.

Further, the driving devices 200, 300 and 400 may be integrated into a single chip. In this case, at least one of the driving devices 200, 300 and 400 or at least one circuit element constituting the driving devices 200, 300 and 400 may be positioned outside the single chip.

As shown in FIG. 2, the organic light emitting device may include a first substrate 110, an organic light emitting element 120 on the first substrate 110, a second substrate 130 facing the first substrate 110, and a seal member 140 attaching the first substrate 110 to the second substrate 130. The drivers 200 and 300 are positioned on the first substrate 110 to supply a driving signal to the organic light emitting element 120.

The organic light emitting element 120 includes a plurality of subpixels (P). The plurality of subpixels (P) are arranged on the first substrate 110 in a matrix format.

The seal member 140 may be formed on the first substrate 110 or the second substrate 130 so as to be positioned outside the organic light emitting element 120. The seal member 140 may include epoxy resin and acryl resin. The seal member 140 may be a sealant or a frit.

Although the seal member 140 is positioned to surround the organic light emitting element 120 in FIG. 2, the exemplary embodiment is not limited thereto. The seal member 140 may be coated on the entire surface of the organic light emitting element 120.

The drivers 200 and 300 include a scan driver for supplying a scan signal to the organic light emitting element 120 and a data driver for supplying a data signal to the organic light emitting element 120.

Although FIG. 2 shows the drivers 200 and 300 for the convenience of explanation as if they are one element, the exemplary embodiment is not limited thereto.

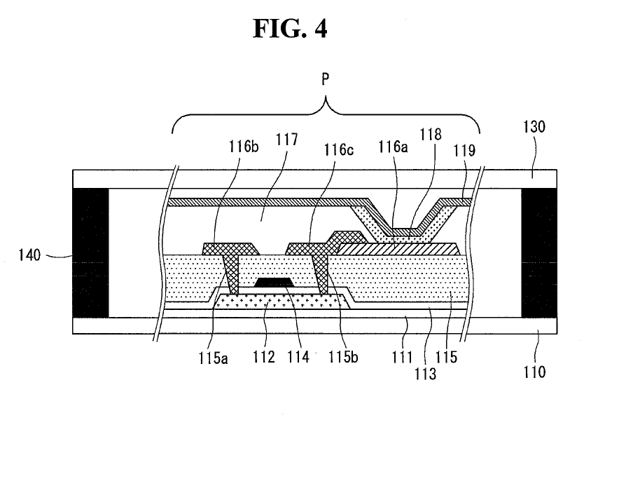

FIG. 4 is a cross-sectional view taken along line Z1-Z2 of FIG. 2.

As shown in FIG. 4, a buffer layer 111 is positioned on the first substrate 110. The buffer layer 111 prevents impurities (e.g., alkali ions discharged from the first substrate 111) from being introduced during formation of the thin film transistor in a succeeding process. The buffer layer 111 may be selectively formed using silicon oxide (SiO₂) and silicon nitride (SiNx), or using other materials.

A semiconductor layer 112 is positioned on the buffer layer 111. The semiconductor layer 112 may include amorphous silicon or polycrystalline silicon.

Although not shown, the semiconductor layer 112 may include a channel area, a source area, and a drain area, and the source area and the drain area may be doped with P-type or N-type impurities.

A gate insulating film 113 is positioned on the first substrate 110 including the semiconductor layer 112. The gate insulating film 113 may be selectively formed using silicon oxide (SiO₂) and silicon nitride (SiNx), or using other materials.

A gate electrode 114 is positioned on the gate insulating film 113 to correspond to a predetermined area, i.e., the channel area of the semiconductor layer 112. The gate electrode 114 may include any one of aluminum (Al), Al alloy, titanium (Ti), silver (Ag), molybdenum (Mo), Mo alloy, tungsten (W), and tungsten silicide (WSi₂).

An interlayer insulating film 115 is positioned on the first substrate 110 including the gate electrode 114. The interlayer insulating film 115 may be an organic film, an inorganic film, or a composite film thereof.

In cast that the interlayer insulating film 115 is an inorganic film, the interlayer insulating film 115 may include silicone oxide (SiO₂), a silicone nitride (SiNx), or silicate-on-glass (SOG). In cast that the interlayer insulating film 115 is an organic film, the interlayer insulating film 115 may include acryl resin, polyimide resin, or benzocyclobutene (BCB) resin. First and second contact holes 115a and 115b are positioned inside the interlayer insulating film 115 and the gate insulating film 113 to expose a portion of the semiconductor layer 112.

A first electrode 116a is positioned on the interlayer insulating film 115. The first electrode 116a may be an anode electrode, and include a transparent conductive layer made of an Indium Tin Oxide (ITO) or an Indium Zinc Oxide (IZO), and the like. The first electrode 116a may have a stacked structure such as ITO/Ag/ITO.

A source electrode 116b and a drain electrode 116c are positioned on the interlayer insulating film 115. The source electrode 116b and the drain electrode 116c are electrically connected to the semiconductor layer 112 through the first contact hole 115a and the second contact hole 115b. Because a portion of the drain electrode 116c is positioned on the first electrode 116a, the drain electrode 116c is electrically connected to the first electrode 116a.

The source electrode 116b and the drain electrode 116c may comprise a low resistance material so as to lower line resistance. The source electrode 116b and the drain electrode 116c may have a multi-layered structure including molybdenum (Mo), moly tungsten (MoW), titanium (Ti), aluminum (Al), or Al alloy. Examples of the multi-layered structure include Ti/Al/Ti or Mo/Al/Mo.

A transistor positioned on the first substrate 110 comprises the gate electrode 114, the source electrode 116b, and the drain electrode 116c. A transistor array including a plurality of transistors and a plurality of capacitors may be electrically connected to an organic light emitting diode to be described later. Accordingly, the subpixel (P) positioned on the first substrate 110 may comprise at least one transistor, at least one capacitor, and at least one organic light emitting diode.

An insulating film 117 is positioned on the first electrode 116a to expose a portion of the first electrode 116a. The insulating film 117 may comprise an organic material such as benzocyclobutene (BCB) resin, acryl resin, or polyimide resin.

An emitting layer 118 is positioned on the exposed portion of the first electrode 116a, and a second electrode 119 is positioned on the emitting layer 118. The second electrode 119 may be a cathode electrode for supplying electrons to the emitting layer 118 and may comprise magnesium (Mg), silver (Ag), calcium (Ca), aluminum (Al), or alloys thereof.

The organic light emitting diode connected to the source electrode 116b or the drain electrode 116c of the transistor array on the first substrate 110 may comprise the first electrode 116a, the emitting layer 118, and the second electrode 119.

The first electrode 116a on the source electrode 116b or the drain electrode 116c of the transistor array may be positioned on a planarization film for planarizing the surface of the transistor array.

Further, a structure of the transistor array may change depending on whether a gate electrode thereof is a top gate structure or a bottom gate structure. Further, a structure of the transistor array may change depending on a material of the semiconductor layer and the number of masks used to form the transistor array. Therefore, a structure of the subpixel of the organic light emitting element 120 is not limited thereto.

The organic light emitting element 120 formed in a thin film form on the first substrate 110 is easily deteriorated by external moisture or oxygen. Therefore, the first substrate 110 and the second substrate 130 face each other and are sealed using the seal member 140 so as to prevent the degradation of the organic light emitting element 120.

The seal member 140 may be formed using a sealant. The seal member 140 may include epoxy resin or acryl resin as a principal component. The material is cured by external light, for example, ultraviolet light to attach the first substrate 110 to the second substrate 130.

Therefore, the higher an absorptance of the cured seal member 140 is, the higher a curing degree of the seal member 140 is. Hence, an airtight characteristic between the sealed substrates can be improved.

The exemplary embodiment may use the seal member 140 having an absorptance of 25% to 35% in a wavelength range of ultraviolet (UV) light as external light of 305 and 330 nm.

The seal member 140 may use a frit. The frit may be made of a material that can be cured by infrared (IR) radiation. Examples of the material include K₂O, Fe₂O₃, Sb₂O₃, ZnO, P₂O₅, V₂O, TiO₂, Al₂O₃, WO₃, Bi₂O₃, SiO₂, B₂O₃, PbO, BaO, TeO as a principal component.

The frit may further include a filler. The filler may include a low expansion ceramic powder such as codierite, zirconyl phosphate, β-eucryptite, β-spodumene, zircon, alumina, mullite, silica, β-quartz solid solution, zinc silicate, aluminum titanate. The filler can operate so that a thermal expansion coefficient of a glass substrate corresponds with a thermal expansion coefficient of the frit.

The frit may further include a transition metal. The transition metal can adjust a thermal expansion characteristic of the frit and an absorption characteristic depending on a frequency of a laser to which will be applied later. Examples of the transition metal include chromium (Cr), iron (Fe), manganese (Mn), cobalt (Co), copper (Cu), vanadium (V).

The frit may further include ZnSiO₄, PbTiO₃, ZrO₂, eucryptite as an additive.

The frit may be formed by coating a frit paste including the above materials on the second substrate 190 using a dispensing method or a screen printing method.

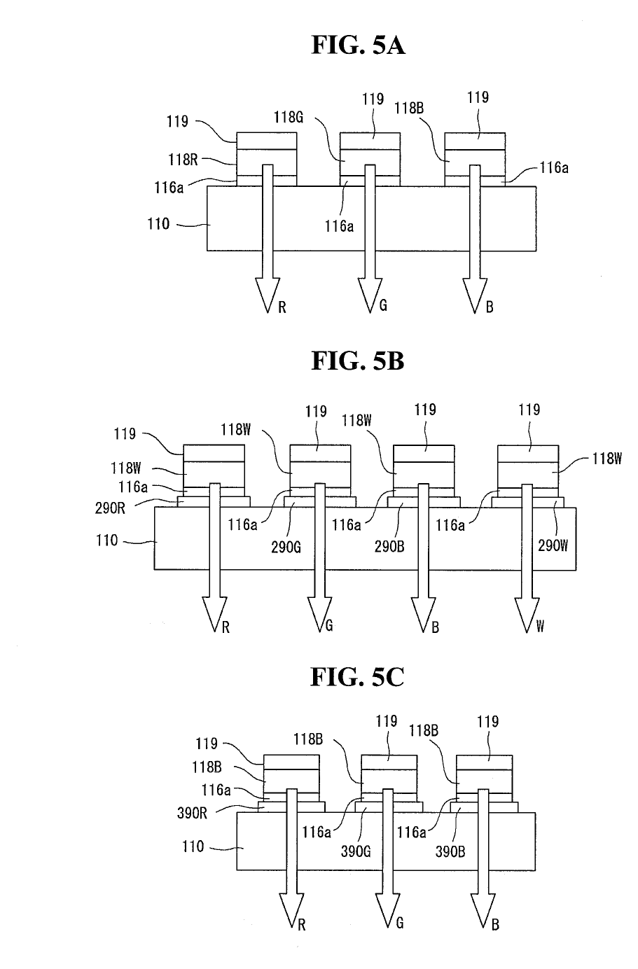

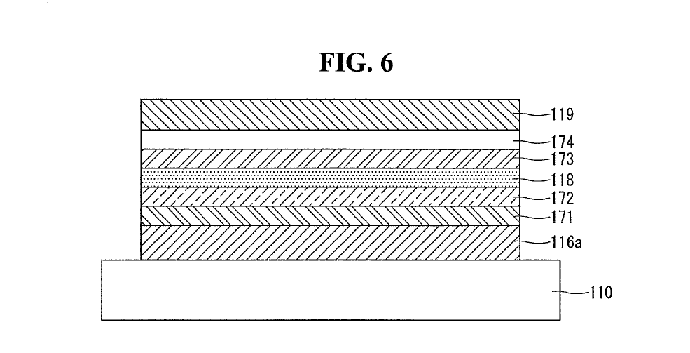

FIGS. 5A to 6C illustrate various implementations of a color image display method in the organic light emitting device.

FIG. 5A illustrates a color image display method in an organic light emitting device separately including a red emitting layer 118R, a green emitting layer 118G and a blue emitting layer 118B which emit red, green and blue light, respectively.

The red, green and blue light produced by the red, green and blue emitting layers 118R, 118G and 118B is mixed to display a color image.

It may be understood in FIG. 5A that the red, green and blue emitting layers 118R, 118G and 118B each include an electron transporting layer, a hole transporting layer, and the like, on upper and lower portions thereof. It is possible to variously change the arrangement and the structure between the additional layers such as the electron transporting layer and the hole transporting layer and each of the red, green and blue emitting layers 118R, 118G and 118B.

FIG. 5B illustrates a color image display method in an organic light emitting device including a white emitting layer 118W, a red color filter 290R, a green color filter 290G, a blue color filter 290B, and a white color filter 290W.

As shown in FIG. 5B, the red color filter 290R, the green color filter 290G, the blue color filter 290B, and the white color filter 290W each transmit white light produced by the white emitting layer 118W to produce red light, green light, blue light, and white light. The red, green, blue, and white light is mixed to display a color image. The white color filter 290W may be removed depending on color sensitivity of the white light produced by the white emitting layer 118W and combination of the white light and the red, green and blue light.

While FIG. 5B has illustrated the color display method of four subpixels using combination of the red, green, blue, and white light, a color display method of three subpixels using combination of the red, green, and blue light may be used.

It may be understood in FIG. 5B that the white emitting layer 118W includes an electron transporting layer, a hole transporting layer, and the like, on upper and lower portions thereof. It is possible to variously change the arrangement and the structure between the additional layers such as the electron transporting layer and the hole transporting layer and the white emitting layer 118W.

FIG. 5C illustrates a color image display method in an organic light emitting device including a blue emitting layer 118B, a red color change medium 390R, a green color change medium 390G, a blue color change medium 390B.

As shown in FIG. 5C, the red color change medium 390R, the green color change medium 390G, and the blue color change medium 390B each transmit blue light produced by the blue emitting layer 118B to produce red light, green light and blue light. The red, green and blue light is mixed to display a color image.

The blue color change medium 390B may be removed depending on color sensitivity of the blue light produced by the blue emitting layer 118B and combination of the blue light and the red and green light.

It may be understood in FIG. 5C that the blue emitting layer 118B includes an electron transporting layer, a hole transporting layer, and the like, on upper and lower portions thereof. It is possible to variously change the arrangement and the structure between the additional layers such as the electron transporting layer and the hole transporting layer and the blue emitting layer 118B.

While FIGS. 5A and 5B have illustrated and described the organic light emitting device having a bottom emission structure, the exemplary embodiment is not limited thereto. The organic light emitting device according to the exemplary embodiment may have a top emission structure, and thus the structure of the organic light emitting device according to the exemplary embodiment may be changed depending on the top emission structure.

While FIGS. 5A to 5C have illustrated and described three kinds of color image display method, the exemplary embodiment is not limited thereto. The exemplary embodiment may use various kinds of color image display method whenever necessary.

FIG. 6 is a cross-sectional view of the organic light emitting device.

As shown in FIG. 6, the organic light emitting device according to the exemplary embodiment includes the substrate 110, the first electrode 116a on the substrate 110, a hole injection layer 171 on the first electrode 116a, a hole transporting layer 172, an emitting layer 170, an electron transporting layer 173, an electron injection layer 174, and the second electrode 119 on the electron injection layer 174.

The hole injection layer 171 may function to facilitate the injection of holes from the first electrode 116a to the emitting layer 170. The hole injection layer 171 may be formed of at least one selected from the group consisting of copper phthalocyanine (CuPc), PEDOT(poly(3,4)-ethylenedioxythiophene), polyaniline (PANI) and NPD(N,N-dinaphthyl-N,N′-diphenyl benzidine), but is not limited thereto. The hole injection layer 171 may be formed using an evaporation method or a spin coating method.

The hole transporting layer 172 functions to smoothly transport holes. The hole transporting layer 172 may be formed from at least one selected from the group consisting of NPD(N,N-dinaphthyl-N,N′-diphenyl benzidine), TPD(N,N′-bis-(3-methylphenyl)-N,N′-bis-(phenyl)-benzidine, s-TAD and MTDATA(4,4′,4″-Tris(N-3-methylphenyl-N-phenyl-amino)-triphenylamine), but is not limited thereto. The hole transporting layer 172 may be formed using an evaporation method or a spin coating method.

The emitting layer 170 may be formed of a material capable of producing red, green, blue or white light, for example, a phosphorescence material or a fluorescence material.

In case that the emitting layer 170 emits red light, the emitting layer 170 includes a host material including carbazole biphenyl (CBP) or N,N-dicarbazolyl-3,5-benzene (mCP). Further, the emitting layer 170 may be formed of a phosphorescence material including a dopant material including any one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum) or a fluorescence material including PBD:Eu(DBM)3(Phen) or Perylene, but is not limited thereto.

In case that the emitting layer 170 emits green light, the emitting layer 170 includes a host material including CBP or mCP. Further, the emitting layer 170 may be formed of a phosphorescence material including a dopant material including Ir(ppy)3(fac tris(2-phenylpyridine)iridium) or a fluorescence material including Alq3(tris(8-hydroxyquinolino)aluminum), but is not limited thereto.

In case that the emitting layer 170 emits blue light, the emitting layer 170 includes a host material including CBP or mCP. Further, the emitting layer 170 may be formed of a phosphorescence material including a dopant material including (4,6-F2ppy)2Irpic or a fluorescence material including any one selected from the group consisting of spiro-DPVBi, spiro-6P, distyryl-benzene (DSB), distyryl-arylene (DSA), PFO-based polymers, PPV-based polymers and a combination thereof, but is not limited thereto.

The electron transporting layer 173 functions to facilitate the transportation of electrons. The electron transporting layer 173 may be formed of at least one selected from the group consisting of Alq3(tris(8-hydroxyquinolino)aluminum, PBD, TAZ, spiro-PBD, BAlq, and SAlq, but is not limited thereto. The electron transporting layer 173 may be formed using an evaporation method or a spin coating method.

The electron transporting layer 173 can also function to prevent holes, which are injected from the first electrode 116a and then pass through the emitting layer 170, from moving to the second electrode 119. In other words, the electron transporting layer 173 serves as a hole stop layer, which facilitates the coupling of holes and electrons in the emitting layer 170.

The electron injection layer 174 functions to facilitate the injection of electrons. The electron injection layer 174 may be formed of Alq3(tris(8-hydroxyquinolino)aluminum), PBD, TAZ, spiro-PBD, BAlq or SAlq, but is not limited thereto.

The electron injection layer 174 may be formed of an organic material and an inorganic material forming the electron injection layer 174 through a vacuum evaporation method.

The hole injection layer 171 or the electron injection layer 174 may further include an inorganic material. The inorganic material may further include a metal compound. The metal compound may include alkali metal or alkaline earth metal.

The metal compound including the alkali metal or the alkaline earth metal may include at least one selected from the group consisting of LiQ, LiF, NaF, KF, RbF, CsF, FrF, BeF₂, MgF₂, CaF₂, SrF₂, BaF₂, and RaF₂, but is not limited thereto.

Thus, the inorganic material inside the electron injection layer 174 facilitates hopping of electrons injected from the second electrode 119 to the emitting layer 170, so that holes and electrons injected into the emitting layer 170 are balanced. Accordingly, emission efficiency can be improved.

Further, the inorganic material inside the hole injection layer 171 reduces the mobility of holes injected from the first electrode 116a to the emitting layer 170, so that holes and electrons injected into the emitting layer 170 are balanced. Accordingly, light emission efficiency can be improved.

At least one of the electron injection layer 174, the electron transporting layer 173, the hole transporting layer 172, the hole injection layer 171 may be omitted.

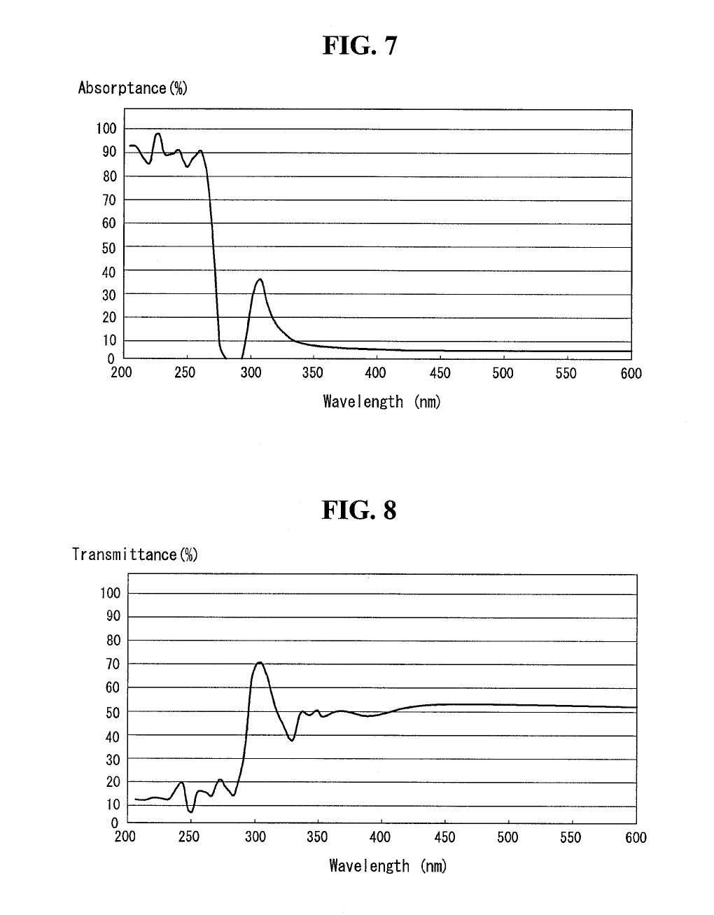

FIG. 7 is a graph showing an absorptance of the seal member of the organic light emitting device.

As shown in FIG. 7, the seal member 140 between the first substrate 110 and the second substrate 130 may have an absorptance of 30% in a wavelength range of ultraviolet light as external light of 305 nm to 330 nm.

Because ultraviolet light used as external light cannot be always irradiated with a constant wavelength due to an external or internal factor, an absorptance of the seal member 140 may have an error range of about ±5% as a deviation. Therefore, the seal member 140 has an absorptance of 25% to 35% within an error range of about ±5% at a UV wavelength of 305 nm to 330 nm.

The seal member 140 may have an absorptance that lies substantially in a range between 25% and 30% at a UV wavelength equal to or longer than 305 nm. Accordingly, because the seal member 140 has an absorptance of 25% to 30% at a low UV wavelength, ultraviolet light having a high wavelength is not required to cure the seal member 140.

The seal member 140 may have an absorptance that lies substantially in a range between 30% and 35% at a UV wavelength equal to or shorter than 330 nm. Accordingly, because the seal member 140 has an absorptance of 30% to 35% at a low UV wavelength, ultraviolet light having a high wavelength is not required to cure the seal member 140.

The graph of FIG. 7 shows that the seal member 140 used in the exemplary embodiment has an absorptance of 25% to 35% at a low UV wavelength.

In other words, the seal member 140 has a proper absorptance in a low UV wavelength, and thus can prevent ultraviolet light radiated for curing the seal member 140 in a sealing process from causing fatal damage to the organic light emitting element 120.

Additionally, at least one of the first substrate 110 and the second substrate 130 transmitting ultraviolet light may be designed in consideration of the amount of ultraviolet light radiated to the seal member 140.

FIG. 8 is a graph showing a transmittance of a substrate of the organic light emitting device.

As shown in FIG. 8, at least one of the first substrate 110 and the second substrate 130 may be formed of a nonmetallic material having a transmittance of 50% to 70% at a wavelength of external light of approximately 305 nm to 330 nm. Examples of the nonmetallic material include glass, but the nonmetallic material is not limited thereto. However, a transmittance of the nonmetallic material may have some error due to a deviation caused by processing characteristics and a wavelength of external light during the manufacturing of the nonmetallic material.

The nonmetallic material may have a transmittance equal to or greater than 50% at a UV wavelength equal to or longer than 305 nm. Accordingly, because the nonmetallic material has a transmittance equal to or greater than 50% at a low UV wavelength, ultraviolet light having a high wavelength is not required to cure the seal member 140.

Even if an absorptance of the seal member 140 is somewhat low, a curing degree can be improved because of a transmittance of the nonmetallic material equal to or greater than 50%.

The nonmetallic material may have a transmittance of approximately 70% at a UV wavelength equal to or shorter than 330 nm. Accordingly, because the nonmetallic material has a transmittance of approximately 70% at a low UV wavelength, ultraviolet light having a high wavelength is not required to cure the seal member 140.

The graph of FIG. 8 shows that the nonmetallic material used in the exemplary embodiment has a transmittance of 70% at a low UV wavelength.

In other words, the nonmetallic material has a proper transmittance in a low UV wavelength, and thus can prevent ultraviolet light radiated to the first or second substrate for curing the seal member 140 in a sealing process from causing fatal damage to the organic light emitting element 120.

For this, at least one of a thermal process or a chemical process may be performed on the surface or in the inside of the first or second substrate made of the nonmetallic material. Further, a shape change, a design of a structure, or the formation of a specific film may occur in a portion of the first or second substrate to which ultraviolet tight is radiated.

Since the organic light emitting device according to the exemplary embodiment includes both the seal member 140 and the nonmetallic material, the sealing condition can be satisfied by the nonmetallic material having the transmittance of 50% to 70% and the seal member 140 having the absorptance of 25% to 35% at a UV wavelength of 305 nm to 330 nm.

In the exemplary embodiment, when the absorptance of the seal member 140 and the transmittance of the nonmetallic material are measured at an equal UV wavelength, a transmittance of the nonmetallic material lies in a range of 50% to 70% so as to increase the absorptance of the seal member 140.

However, even if a transmittance of the nonmetallic material is equal to or greater than 30% at a UV wavelength of 305 nm to 330 nm under the above-described sealing condition, the seal member 140 may be cured.

A glass transition temperature (Tg) of the seal member 140 may lie substantially in a range between 100 and 200° C., or 120 and 180° C.

When the glass transition temperature (Tg) of the seal member 140 is equal to or higher than 100° C., the deformation of the seal member 140 caused by a phase change in the seal member 140 during a thermal process can be prevented. Hence, a reduction in the adhesive strength can be prevented. When the glass transition temperature (Tg) of the seal member 140 is equal to or lower than 200° C., the processing difficulty of keeping a high temperature environment during a dispensing process for coating the seal member 140 can be solved.

Further, the adhesive strength of the seal member 140 may lie substantially in a range between 5 and 200 kg f/cm², or 20 and 150 kg f/cm².

The adhesive strength of the seal member 140 may change depending on a material of the first substrate 110. In case that the first substrate 110 is made of glass, an adhesive strength between the first substrate 110 and the seal member 140 may lie substantially in a range between 5 and 20 kg f/cm².

When the adhesive strength of the seal member 140 is equal to or greater than 5 kg f/cm², impact resistance of a product can be improved by preventing the seal member 140 from easily coming out by external impact after the organic light emitting device is completely manufactured. The adhesive strength of the seal member 140 may be equal to or smaller than approximately 200 kg f/cm² because of a reason of the process limitation although the greater the adhesive strength of the seal member 180 is better.

As described above, since the organic light emitting device according to the exemplary embodiment is sealed in consideration of the transmittance of the substrate and the absorptance of the seal member, life span and the reliability of the organic light emitting device can be improved.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. An organic light emitting device comprising:
a first substrate;
an organic light emitting element on the first substrate, the organic light emitting element including an emitting layer, at least one of layers constituting the emitting layer including a phosphorescence material;
a second substrate that faces the first substrate; and
a seal member that attaches the first substrate to the second substrate, the seal member having an absorptance that lies substantially in a range between 25% and 35% at a wavelength of external light of approximately 305 nm to 330 nm.

2. The organic light emitting device of claim 1, wherein the organic light emitting element includes a transistor array on the first substrate, and a plurality of organic light emitting diodes electrically connected to the transistor array.

3. The organic light emitting device of claim 1, wherein a glass transition temperature of the seal member lies substantially in a range between 120° C. and 180° C.

4. The organic light emitting device of claim 1, wherein an adhesive strength of the seal member lies substantially in a range between 5 kgf/cm² and 20 kgf/cm².

5. The organic light emitting device of claim 1, wherein the seal member includes epoxy resin or acryl resin.

6. The organic light emitting device of claim 1, wherein the seal member is positioned outside the organic light emitting element.

7. The organic light emitting device of claim 1, wherein the seal member is a sealant or a frit.

8. An organic light emitting device comprising:
a first substrate;
an organic light emitting element on the first substrate, the organic light emitting element including an emitting layer, at least one of layers constituting the emitting layer including a phosphorescence material;
a second substrate facing the first substrate; and
a seal member that attaches the first substrate to the second substrate, the seal member having an absorptance that lies substantially in a range between 25% and 35% at a wavelength of external light of approximately 305 nm to 330 nm,
wherein at least one of the first substrate and the second substrate has a transmittance that lies substantially in a range between 50% and 70% at a wavelength of external light of approximately 305 nm to 330 nm.

9. The organic light emitting device of claim 8, wherein the organic light emitting element includes a transistor array on the first substrate, and a plurality of organic light emitting diodes electrically connected to the transistor array.

10. The organic light emitting device of claim 8, wherein a glass transition temperature of the seal member lies substantially in a range between 120° C. and 180° C.

11. The organic light emitting device of claim 8, wherein an adhesive strength of the seal member lies substantially in a range between 5 kgf/cm² and 20 kgf/cm².

12. The organic light emitting device of claim 8, wherein the seal member includes epoxy resin or acryl resin.

13. The organic light emitting device of claim 8, wherein the seal member is positioned outside the organic light emitting element.

14. The organic light emitting device of claim 8, wherein the seal member is a sealant or a frit.

15. An organic light emitting device comprising:
a first substrate;
an organic light emitting element on the first substrate, the organic light emitting element including an emitting layer, at least one of layers constituting the emitting layer including a phosphorescence material;
a second substrate facing the first substrate; and
a seal member that attaches the first substrate to the second substrate,
wherein the seal member has an absorptance that lies substantially in a range between 25% and 35% at a wavelength of external light of approximately 305 nm to 330 nm, and a water vapor permeation rate greater than 0 and equal to or less than 10⁻² g/m²/day, and
at least one of the first substrate and the second substrate has a transmittance that lies substantially in a range between 50% and 70% at a wavelength of external light of approximately 305 nm to 330 nm.

16. The organic light emitting device of claim 15, wherein the organic light emitting element includes a transistor array on the first substrate, and a plurality of organic light emitting diodes electrically connected to the transistor array.

17. The organic light emitting device of claim 15, wherein a glass transition temperature of the seal member lies substantially in a range between 120° C. and 180° C.

18. The organic light emitting device of claim 15, wherein an adhesive strength of the seal member lies substantially in a range between 5 kgf/cm² and 20 kgf/cm².

19. The organic light emitting device of claim 15, wherein the seal member includes epoxy resin or acryl resin.

20. The organic light emitting device of claim 15, wherein the seal member is positioned outside the organic light emitting element.

21. The organic light emitting device of claim 15, wherein the seal member is a sealant or a frit.
